(19) United States
(12) Patent Application Publication
(10) Pub. No.: US 2024/0093984 A1
(43) Pub. Date: Mar. 21, 2024

(54) FRINGE PROJECTOR FOR DEPTH SENSING

(71) Applicant: Meta Platforms Technologies, LLC, Menlo Park, CA (US)

(72) Inventors: Guohua Wei, Redmond, WA (US); Petr Markov, Seattle, WA (US); Qing Chao, Redmond, WA (US)

(21) Appl. No.: 18/088,302

(22) Filed: Dec. 23, 2022

Related U.S. Application Data
(60) Provisional application No. 63/319,772, filed on Mar. 15, 2022.

(51) Int. Cl. G01B 11/25; G02B 6/12; G02B 27/00; G02B 27/01; G06V 40/18; H01S 5/183; H01S 5/40

(52) U.S. Cl. CPC G01B 11/2513; G02B 6/12004; G02B 27/0093; G02B 27/017; G06V 40/18; H01S 5/18305; H01S 5/4031; G02B 2006/12038; G02B 2006/1204; G02B 2006/12061; G02B 2027/0178; G06V 2201/12

(57) ABSTRACT

An optical system is configured to support eye tracking operations in a head mounted device. The optical system includes a transparent layer, a laser, and first and second output couplers. The laser is configured to emit light into the transparent layer. The first output coupler is configured to out-couple a first portion of the light from a first location of the transparent layer. The second output coupler is configured to out-couple a second portion of the light from a second location of the transparent layer. The first and second output couplers are in the field-of-view of a user. A combination of the first portion of the light and the second portion of the light out-coupled from the first output coupler and the second output coupler is configured to generate a fringe pattern, for example, on an eye of a user of the head mounted device.

### CROSS-REFERENCE TO RELATED APPLICATIONS

This application claims priority to U.S. Provisional Application No. 63/319,772 filed Mar. 15, 2022, which is hereby incorporated by reference.

### TECHNICAL FIELD

This disclosure relates generally to eye tracking, and in particular to illumination for eye tracking.

### BACKGROUND INFORMATION

Current 3D sensing technologies (such as structured light), especially for the near range, suffer from noisy and lower quality depth maps. The noise and quality deficit of depth maps can be attributed to significant down-sampling of camera images.

### BRIEF DESCRIPTION OF THE DRAWINGS

Non-limiting and non-exhaustive embodiments of the invention are described with reference to the following figures, wherein like reference numerals refer to like parts throughout the various views unless otherwise specified.

FIGS. 1A and 1B illustrate an example head mounted device having a fringe projector, in accordance with aspects of the present disclosure.

FIGS. 2A and 2B illustrate example cross-sectional views of an optical element that includes an illumination layer having components of a fringe projector, in accordance with an embodiment of the disclosure.

FIG. 3 illustrates a partial view of a head mounted device having phase shifted fringe projector with a tunable laser, in accordance with aspects of the present disclosure.

FIG. 4 illustrates a partial view of a head mounted device having two fringe projectors coupled to an optical element, in accordance with aspects of the disclosure.

FIG. 5 illustrates a partial view of a head mounted device having two fringe projectors operating on different wavelengths, in accordance with aspects of the disclosure.

FIGS. 6A, 6B, 6C, and 6D illustrate various light source and sensor configurations for a head mounted device, in accordance with aspects of the disclosure.

FIGS. 7A, 7B, and 7C illustrate various aspects of interferometric fringe generation with pinhole separation and fringe spatial frequencies, in accordance with aspects of the disclosure.

FIG. 8 illustrates an example flow diagram of a process for depth sensing with a head mounted device, in accordance with aspects of the disclosure.

### DETAILED DESCRIPTION

Embodiments of a fringe projector for depth sensing are described herein. In the following description, numerous specific details are set forth to provide a thorough understanding of the embodiments. One skilled in the relevant art will recognize, however, that the techniques described herein can be practiced without one or more of the specific details, or with other methods, components, materials, etc. In other instances, well-known structures, materials, or operations are not shown or described in detail to avoid obscuring certain aspects.

Reference throughout this specification to “one embodiment” or “an embodiment” means that a particular feature, structure, or characteristic described in connection with the embodiment is included in at least one embodiment of the present invention. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

Throughout this specification, several terms of art are used. These terms are to take on their ordinary meaning in the art from which they come, unless specifically defined herein or the context of their use would clearly suggest otherwise.

In some embodiments of the disclosure, “near-eye” may be defined as including an optical element that is configured to be placed within 35 mm of an eye of a user while a near-eye optical device such as a head mounted device is being utilized.

Eye region or eyebox region may be defined as a region of interest that includes an area or a volume next to a lens assembly where an eye of a user is located or may be located while using a head mounted device. The eye region or eyebox region may have height dimensions of 8 mm to 20 mm, width dimensions of 10 mm to 20 mm, and depth dimensions of 5 mm to 25 mm, in some implementations.

Current 3D sensing technologies (such as structured light), especially for near range, suffer from noisy and lower quality depth maps. The noise and low quality are mainly due to significant down-sampling of camera images. Fringe illumination-based (3D) depth sensing can provide denser and more accurate depth maps. To obtain more accurate 3D shapes using fringe-based depth sensing, embodiments of the disclosure include a compact, versatile, and efficient fringe projector that can be implement in head mounted devices (e.g., smart glasses, augmented reality headset, or virtual reality headset). The fringe projectors may be used for eye tracking, face tracking, and/or hand tracking.

Implementations of this disclosure propose compact and inconspicuous fringe projectors directly formed on a transparent substrate that can be positioned in a field-of-view (FOV) of a user without obscuring or blocking a user's see-through view of a scene. Thus, implementations of the disclosure may be suitable for AR/VR applications. Photonic integrated circuits that may provide these features may include static phase shifting, a tunable laser for phase shifting, and/or wavelength multiplexing.

A head mounted device may include a depth sensing system to support eye tracking operations. The depth sensing system may include a fringe projector to generate a fringe pattern, a sensor (e.g., image sensor), and a controller.

The fringe projector may include a laser, a waveguide structure, and two outcoupling elements to generate a fringe pattern, for example, on an eye of a user. The laser may be positioned within a frame of the head mounted device and may be configured emit a light beam into a transparent layer of a lens assembly. The light beam may be a Gaussian beam. The wavelength of the light beam may be chirped (e.g., ramped up and/or down over time) or adjusted to alter characteristics of the fringe pattern.

The waveguide structure may include two channels. Each of the channels may be optically coupled to one of two outcoupling elements. The channels propagate light from the laser to the outcoupling elements. The waveguide structure may have two independent channels that couple the light source to the outcoupling elements. The waveguide structure may have a shared channel that is split into two independent channels that enable separation of the outcoupling elements. One of the channels may be elongated to optically delay the phase of light passing through the elongated channel. Delaying the phase of light for one channel and not the other channel may be combined with sweeping the wavelength of the laser to modify (e.g., move left, right, up, down) the interference lines of the fringe pattern.

The outcoupling elements may be placed directly in front of the eye of a user to enable fringe projection from in front of the eye. The outcoupling elements may be fabricated in a transparent layer of the lens assembly and may be unnoticeably small (e.g., 3 μm×3 μm). The outcoupling elements may be mirrors, grating couplers, or some other optical output coupler. The outcoupling elements are configured to redirect light beam from the waveguide structure to an eye region.

A sensor may be coupled to the frame and may be oriented towards the eye region to capture reflections of a fringe pattern off of an eye. The sensor may provide image data that is representative of the reflections to a controller. The controller may determine or generate a depth map of the eye region based on the image data, according to an embodiment.

The depth sensing system may have a variety of configurations. For example, one lens assembly (or optical element) may include two or more waveguide structures that direct light to two or more pairs of outcoupling elements. Each waveguide structure may be coupled to its own laser. The lasers may be operated concurrently or sequentially. The lasers may be configured to operate on two different wavelengths (e.g., 850 nm and 940 nm) to provide fringe patterns of different wavelengths to improve depth sensing. The outcoupling elements of multiple fringe projectors may be interleaved and inline with each other, may be perpendicular to each other, or may be offset from one another at a variety of angles. Multiple pairs of outcoupling elements may be positioned close to each other in a lens assembly so as to generate fringe patterns with approximately the same center point. One or sensors may be positioned around the frame of the head mounted device to image the fringe patterns. The one or more sensors may be configured to image different wavelengths, may be configured to image one or two specific wavelengths (e.g., 850 nm and 940 nm), and/or may be configured to image one or more fringe patterns from different locations on the frame.

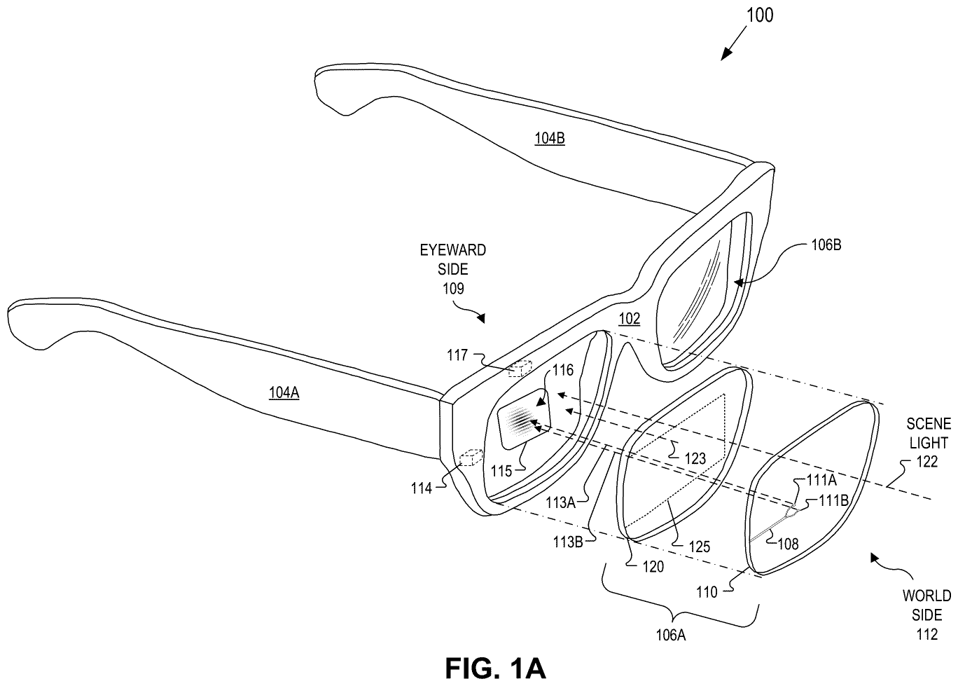

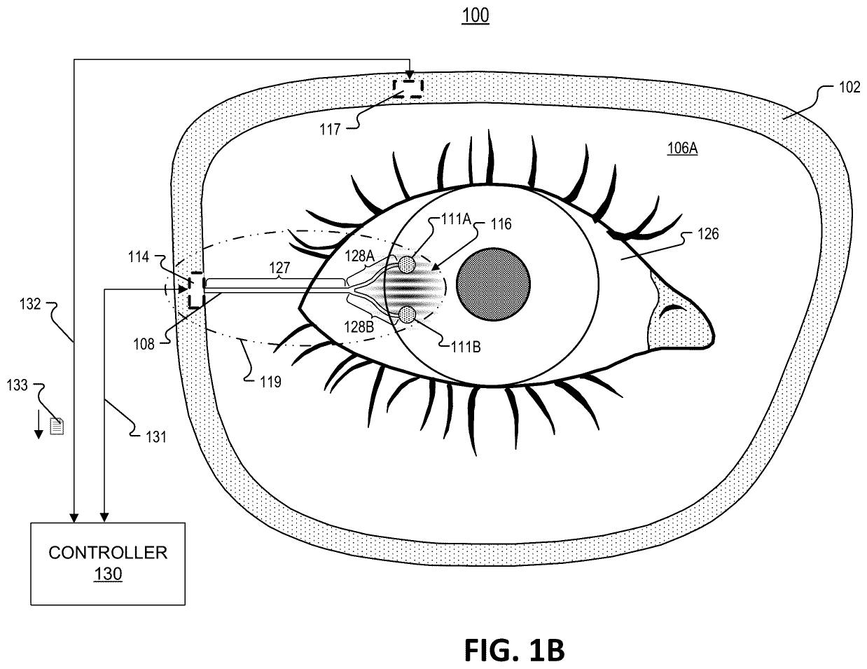

The apparatus, system, and method for depth sensing that are described in this disclosure may enable improvements in eye tracking technologies, for example, to support operations of a head mounted device. These and other embodiments are described in more detail in connection with FIGS. 1A-8

FIG. 1A illustrates an example head mounted device 100 having a fringe projector, in accordance with aspects of the present disclosure. The fringe projector is configured to project a fringe pattern onto an eye from directly in front of the eye, according to an embodiment. The fringe projector may improve 3D depth sensing of the eye, at least partially based on the projection of the fringe pattern directly in front of the eye. A head mounted device, such as head mounted device 100, is one type of smart device. In some contexts, head mounted device 100 is also a head mounted display (HMD). Artificial reality is a form of reality that has been adjusted in some manner before presentation to the user, which may include, e.g., virtual reality (VR), augmented reality (AR), mixed reality (MR), hybrid reality, or some combination and/or derivative thereof.

The illustrated example of head mounted device 100 is shown as including a frame 102, temple arms 104A and 104B, and optical elements 106A and 106B. FIG. 1A also illustrates an exploded view of an example of optical element 106A. Optical element 106A is shown as including an illumination layer 110 and a display layer 120.

As shown in FIG. 1A, frame 102 is coupled to temple arms 104A and 104B for securing the head mounted device 100 to the head of a user. Example head mounted device 100 may also include supporting hardware incorporated into the frame 102 and/or temple arms 104A and 104B. The hardware of head mounted device 100 may include any of processing logic, wired and/or wireless data interfaces for sending and receiving data, graphic processors, and one or more memories for storing data and computer-executable instructions. In one example, head mounted device 100 may be configured to receive wired power and/or may be configured to be powered by one or more batteries. In addition, head mounted device 100 may be configured to receive wired and/or wireless data including video data.

FIG. 1A illustrates optical elements 106A and 106B that are configured to be mounted to the frame 102. Frame 102 may house optical elements 106A and 106B by surrounding at least a portion of a periphery of optical elements 106A and 106B. Optical element 106A is configured to receive visible scene light 122 at a world side 112 of optical element 106A. Visible scene light 122 propagates through optical element 106A to an eye of a user of head mounted device 100 on an eyeward side 109 of optical element 106A. In some examples, optical element 106A may be transparent or semi-transparent to the user to facilitate augmented reality or mixed reality such that the user can view visible scene light 122 from the environment while also receiving display light 123 directed to their eye(s) by way of display layer 120. A waveguide 125 included in display layer 120 may be utilized to direct the display light 123 generated by an electronic display towards eyeward side 109, although other display technologies may also be utilized in display layer 120. In some implementations, at least a portion of an electronic display is included in frame 102 of the head mounted device 100. The electronic display may include an LCD, an organic light emitting diode (OLED) display, micro-LED display, pico-projector, or liquid crystal on silicon (LCOS) display for generating the display light 123.

In further examples, some or all of optical elements 106A and 106B may be incorporated into a virtual reality headset where the transparent nature of optical elements 106A and 106B allows the user to view an electronic display (e.g., a liquid crystal display (LCD), an organic light emitting diode (OLED) display, a micro-LED display, etc.) incorporated in the virtual reality headset. In this context, display layer 120 may be replaced by the electronic display.

Illumination layer 110 may be configured to project fringe pattern 116 from in-field (within a field-of-view) and from directly in front of eye region 115, in accordance with aspects of the disclosure. Illumination layer 110 includes a transparent layer that may be formed of optical polymers, glasses, silicon dioxide (SiO₂), transparent wafers (such as high-purity semi-insulating SiC wafers) or any other transparent materials used for this purpose. Illumination layer 110 includes a waveguide structure 108 and outcoupling elements 111A and 111B. Waveguide structure 108 and outcoupling elements 111A and 111B are configured to receive light from light source 114 and are configured to emit light beams 113A and 113B to generate fringe pattern 116.

Light beams 113A and 113B may be near-infrared light beams, in some aspects. Light source 114 generates non-visible light (e.g., laser beam) for waveguide structure 108 and may include one or more of a vertical cavity surface emitting laser (VCSEL), on-chip integrated laser, hybrid integrated laser, or an edge emission laser. Light source 114 may be a VCSEL configured to emit with a wavelength in the near infrared range, such as 750-1550 nm. Light source 114 may be a VCSEL that has a single transverse mode. Light source 114 may be a VCSEL with a single junction or with multiple junctions. Light source 114 may be an edge emission laser that is implemented as a FP (Fabry-Perot) or a DFB (distributed feedback) laser. Light source 114 may be a light source that is coupled to waveguide 108 with a microoptical bench. Light source 114 may be a VCSEL with emitters facing toward waveguide structure 108, and light from light source 114 may be incoupled into waveguide structure 108 through a grating coupler or some other input coupler. Light source 114 may be an edge emission laser that is coupled with the waveguides through butt coupling. Light source 114 may be enclosed in frame 102 to be out of the field-of-view (FOV) of a user.

A waveguide structure 108 is configured to receive non-visible light from light source 114, which is coupled to frame 102. In one implementation, waveguide structure 108 may include two independent channels from light source 114 to outcoupling elements 111A and 111B. In one implementation, waveguide structure 108 may include a waveguide splitter that distributes the light from a common channel (e.g., segment 127 shown in FIG. 1B) into multiple (e.g., two) independent channels (e.g., segments 128A and 128B shown in FIG. 1B). A waveguide splitter may be used to split the power in one waveguide into multiple waveguides. For example, a Y shaped splitter can divide a single waveguide into two channels with balanced power or designed unbalanced power. A 1×2 MMI (multimode interferometer) coupler can function similarly to a Y splitter, a 1×4 MMI splitter can divide a single waveguide into 4 channels, and so on. A Mach-Zehnder interferometer can also be used for splitting the optical power of waveguide structure 108. Waveguide structure 108 is formed with a rectangular cross section shape of a material with a higher refractive index than its surroundings, according to an embodiment. The higher refractive index material may have a very low absorption for the operating wavelength to support light propagating in the waveguide with less loss. Dimensions of waveguide structure 108 may be selected to form a light beam (e.g., light beam 113A and 113B) with a designed profile, such as Gaussian or elliptical Gaussian. Waveguide dimensions and waveguide material index may be selected to generate a designed beam divergence angle (e.g., 5-15°). The height and width of waveguide structure 108 may be in the range of 100 nm to 10 μm, for example.

Waveguide structure 108 is configured to deliver the non-visible light from light source 114 to outcoupling elements 111A and 111B. Only one waveguide structure 108 and one pair of outcoupling elements 111A and 111B are illustrated in FIGS. 1A and 1B. However, there may be a plurality of waveguides and a plurality of pairs outcoupling elements, in some implementations. Outcoupling elements 111A and 111B are configured to outcouple the non-visible light propagating in waveguide structure 108 as non-visible light beams 113A and 113B to illuminate eye region 115 with fringe pattern 116. Fringe pattern 116 is generated by the constructive and destructive interference of light beams 113A and 113B as they propagate from optical element 106A to eye region 115. The spacing between the waveguides channels or outcoupling elements 111A and 111B is selected for a particular fringe frequency (e.g., spatial frequency) of fringe pattern 116, according to an embodiment. The spacing between outcoupling elements 111A and 111B may be 20-80 μm, for example. In one implementation, the spacing between outcoupling elements 111A and 111B is 40 μm.

As shown in FIGS. 1A and 1B, outcoupling elements 111A and 111B and waveguide structure 108 are disposed within the FOV provided to a user by optical element 106A. While outcoupling elements 111A and 111B may introduce minor occlusions or non-uniformities into optical element 106A, outcoupling elements 111A and 111B and waveguide structure 108 may be so small as to be unnoticeable or insignificant to a wearer of head mounted device 100. Additionally, any occlusion from outcoupling elements 111A and 111B and waveguide structure 108 may be placed so close to the eye as to be unfocusable by the human eye and therefore outcoupling elements 111A and 111B and waveguide structure 108 will not be noticeable to a user of head mounted device 100. Waveguide structure 108 includes a transparent (to visible light) dielectric material, such as silicon nitride (SiN), silicon (Si), or lithium niobate, in some implementations. Waveguide structure 108 includes a refractive index that is greater than the refractive index of the transparent material of illumination layer 110. Furthermore, outcoupling elements 111A and 111B and waveguide structure 108 may be so small that even an observer (a person not wearing device 100 but viewing device 100) may not notice outcoupling elements 111A and 111B and waveguide structure 108. Outcoupling elements 111A and 111B may be smaller than 20 μm at the widest/longest dimension. In an implementation, outcoupling elements 111A and 111B are smaller than 5 μm at the widest/longest dimension. In an implementation, outcoupling elements 111A and 111B have a width of 3 μm and a length of 3 μm. Outcoupling elements 111A and 111B may be implemented as mirrors, grating couplers, or another type of output coupler.

Head mounted device 100 may include a sensor 117 that is configured to capture reflections of fringe pattern 116 from eye region 115, according to an embodiment. Sensor 117 may be oriented towards eye region 115 and may be configured to capture reflections directly from an eye (e.g., eye 126 shown in FIG. 1B). In some implementations, a combiner layer (not illustrated) is optionally disposed between display layer 120 and illumination layer 110 to direct reflected fringe pattern 116 towards sensor 117. Sensor 117 may include a complementary metal-oxide semiconductor (CMOS) image sensor. When light beams 113A and 113B are infrared light, an infrared filter that receives a narrow-band infrared wavelength may be placed over the image sensor so it is sensitive to the narrow-band infrared wavelength while rejecting wavelengths outside the narrow-band, including visible light wavelengths.

In some implementations, optical element 106A may have a curvature for focusing light (e.g., display light 123) to the eye of the user. The curvature may be included in the transparent layer of illumination layer 110. Thus, optical element 106A may be referred to as a lens. In some aspects, optical element 106A may have a thickness and/or curvature that corresponds to the specifications of a user. In other words, optical element 106A may be considered a prescription lens.

FIG. 1B illustrates a flattened front view of a portion of head mounted device 100 and includes fringe projector 119, in accordance with aspects of the disclosure. Fringe projector 119 includes light source 114, waveguide structure 108, and outcoupling elements 111A and 111B, according to an embodiment. As illustrated, fringe projector is configured to project fringe pattern 116 onto an eye 126 of the user of head mounted device 100. As illustrated, waveguide structure 108 may have a segment 127 that is coupled to and split into segments 128A and 128B. Segment 127 is coupled to light source 114 and to segments 128A and 128B. Segments 128A and 128B are coupled to outcoupling elements 111A and 111B, respectively. Segments 128A and 128B may have approximately the same length so that the phase of light beam 113A is the same as the phase of light beam 113B, in one implementation. In other implementations, the length of one of segments 128A and 128B may be elongated or shortened to change the phase of light in one segment (channel) with respect to the phase of light in another segment (channel).

Head mounted device 100 includes a controller 130 that is configured to provide control signals and receive image data 133, in accordance with aspects of the disclosure. Controller 130 may be coupled to light source 114 through a communication channel 131. Controller 130 may provide control signals/instructions to light source 114 that synchronizes the operation of light source 114 with the operation of sensor 117. Controller 130 may provide control signals/instructions to light source 114 to define or modify the emission wavelength of light source 114. Controller 130 may be coupled to sensor 117 through a communication channel 132. Controller 130 may receive image data 133 of fringe pattern 116 from sensor 117. Controller 130 may be configured to generate a depth map of eye 126 based on image data 133. Controller may include one or more processors, a field-programmable gate array (FPGA) chip, and one or more memories. Controller 130 may be coupled to or embedded in frame 102 or in one or more arms 104A and 104B.

Fringe projector 119 may be used to perform depth sensing of objects other than an eye. In implementations, fringe projector 119 may be used to project fringe pattern 116 on an eye, a hand, or a face for depth sensing and/or imaging purposes.

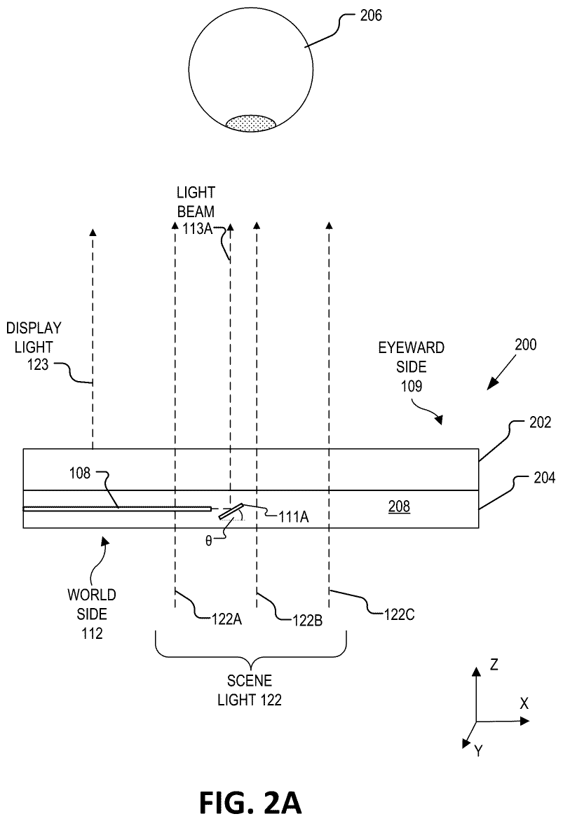

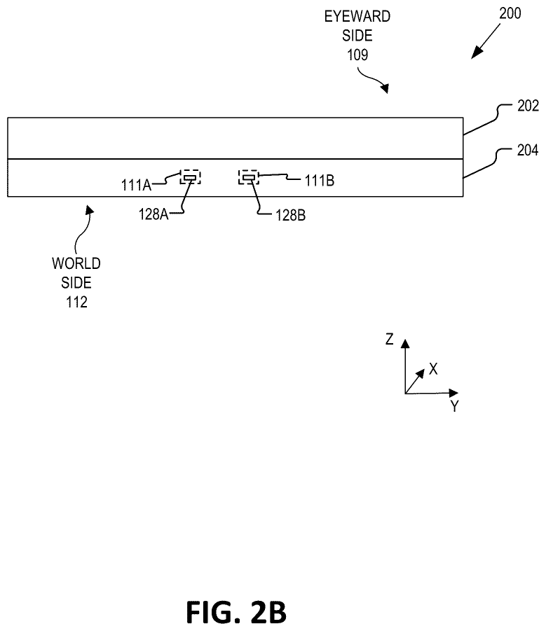

FIGS. 2A and 2B are cross-sectional views of an optical element 200, in accordance with aspects of the present disclosure.

FIG. 2A is a cross-sectional x-axis and z-axis view of optical element 200, in accordance with aspects of the present disclosure. Optical element 200 is an example implementation of optical element 106A (shown in FIG. 1A). The illustrated example of optical element 200 is shown as including a display layer 202 and an illumination layer 204. Also shown in FIG. 2A is an eye 206 of a user of the head mounted device.

As shown in FIG. 2A, the display layer 202 is configured to direct visible display light 123 towards the eyeward side 209 of the optical element 200 for presenting one or more virtual graphics to the eye 206. The optical element 200 is also shown as receiving visible scene light 122A-122C from world side 112, where optical element 200 is configured to direct the visible scene light 122A-122C to eyeward side 109 for viewing by the eye 206. Illumination layer 204 is shown as including waveguide structure 108 optically coupled to outcoupling element 111A. Light beam 113A is emitted by waveguide structure 108 and is directed towards eye 206 by outcoupling element 111A. Outcoupling element 111A may be positioned or fabricated with a (diffractive or reflective) angle θ, which may be 45°, greater than 45°, or less than 45°. Waveguide structure 108 and outcoupling element 111A (and 111B) may be embedded within a transparent material 208 of illumination layer 204. In implementations, waveguide structure 108 and outcoupling elements 111A and 111B may be fabricated on or close to a surface of illumination layer 204. FIG. 2A also illustrates a cross-section of waveguide structure 108 having a higher index material (e.g., silicon nitride) being surrounded by transparent material 208 having a lower index material (e.g., silicon dioxide).

FIG. 2B is a cross-sectional y-axis and z-axis view of optical element 200, in accordance with aspects of the present disclosure. In particular, FIG. 2B shows segments 128A and 128B of waveguide structure 108 going into illumination layer 204 to provide light to outcoupling elements 111A and 111B, according to one example implementation.

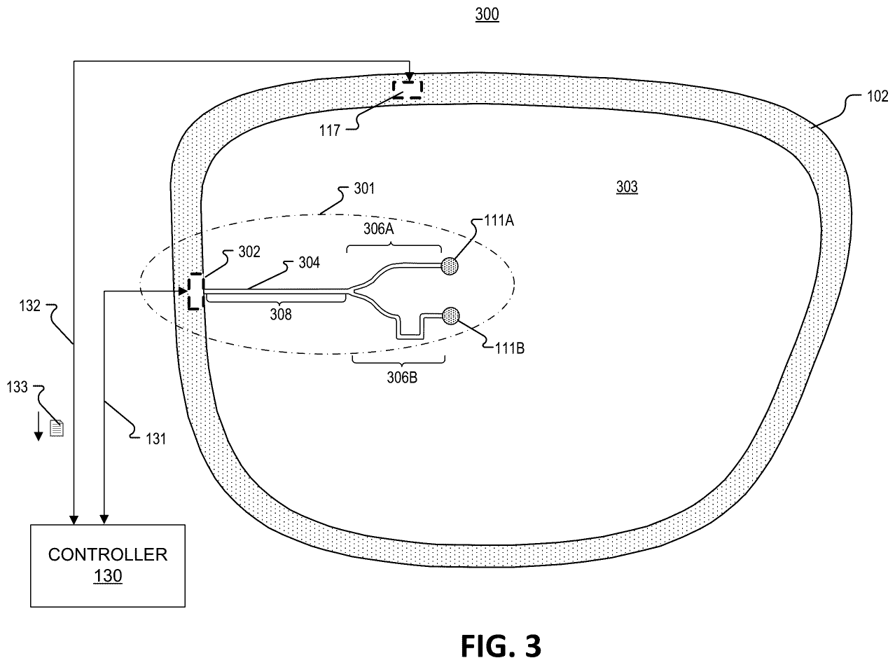

FIG. 3 illustrates a partial view of a head mounted device 300 having phase shifted fringe projector 301 with a tunable laser 302. Tunable laser 302 is coupled to frame 102 and is configured to emit a light beam into an illumination layer of optical element 303. Optical element 303 carries a waveguide structure 304 that is optically coupled to receive a light beam from tunable laser 302. When tunable laser 302 is used as the light source, the wavelength of the laser may be adjusted or chirped (i.e., ramped up and/or ramped down). When the wavelength of tunable laser 302 is adjusted or chirped, the phase of the light beam that exits segment 306A of waveguide structure 304 will be different than the light beam that exits segment 306B of waveguide structure 304. A segment 308 of waveguide structure 304 may be common to outcoupling elements 111A and 111B or may be bifurcated and modified similarly to segment 306B (with respect to segment 306A). The change associated with the wavelength change of tunable laser 302 causes the fringe pattern to shift (e.g., up, down, left, and/or right), which enables greater coverage of an eye, according to an embodiment.

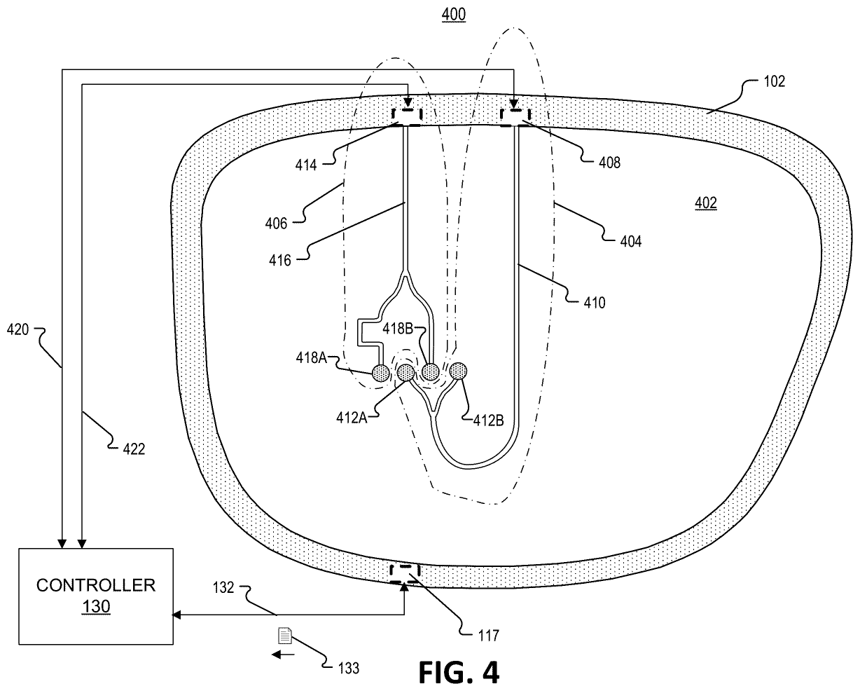

FIG. 4 illustrates a partial view of a head mounted device 400 having two fringe projectors coupled to an optical element 402, in accordance with aspects of the disclosure. A fringe projector 404 is configured to provide a fringe pattern without shifting the phase of one of its output light beams, and fringe projector 406 has a phase shifting channel that has an optical delay, according to an embodiment. Fringe projector 406 has a phase shifting channel because the optical path lengths from the light source to the outcoupling elements are different.

Fringe projector 404 includes a light source 408, a waveguide structure 410, and outcoupling elements 412A and 412B, according to an embodiment. Light source 408 may be a tunable laser with an emission wavelength that may be varied or chirped. A portion of the channel of waveguide structure 410 may be curved to at least partially interleave outcoupling elements 412A and 412B of fringe projector 404 with the outcoupling elements of fringe projector 406.

Fringe projector 406 includes a light source 414, a waveguide structure 416, and outcoupling elements 418A and 418B, according to an embodiment. Light source 414 may be a tunable laser with an emission wavelength that may be varied or chirped, which may cause the fringe pattern generated by fringe projector 406 to shift on an eye. A first segment (or channel) of waveguide structure 416 may be longer than a second segment (or channel) to insert an optical delay to shift the phase of the light beam output from outcoupling element 418A, with respect to the phase of the light beam output from outcoupling element 418B. Changing the frequency or wavelength of light source 414 may cause the output light beams to constructively and destructively interfere at different locations—causing the dark and light interference patterns of the generated fringe pattern to shift (e.g., left and right).

Controller 130 may be coupled to light source 408, light source 414, and sensor 117. Controller 130 may be communicatively coupled to light source 408 through a communication channel 420 to send control signals to turn light source 408 on and off and to set or adjust the operating wavelength or frequency of light source 408. Controller 130 may be communicatively coupled to light source 414 through a communication channel 422 to send control signals to turn light source 414 on and off and to set or adjust the operating wavelength or frequency of light source 414.

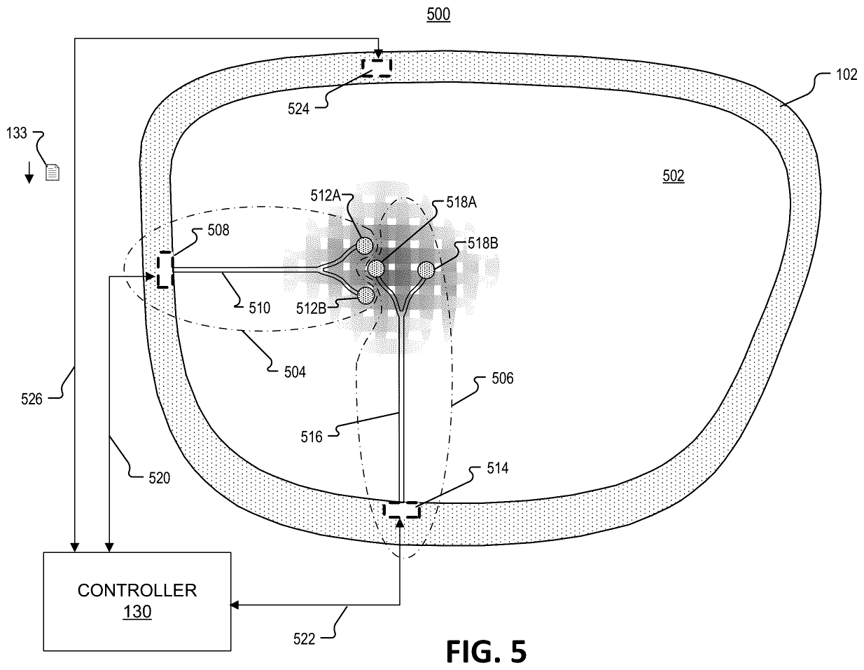

FIG. 5 illustrates a partial view of a head mounted device 500 having two fringe projectors operating on different wavelengths coupled to an optical element 502, in accordance with aspects of the disclosure. A fringe projector 504 is configured to provide a first fringe pattern at a first wavelength (e.g., 850 nm), and a fringe projector 506 is configured to provide a second fringe pattern at a second wavelength (e.g., 940 nm), according to an embodiment. Fringe projector 504 and fringe projector 506 may be operated concurrently to illuminate the eye with two fringe patterns at two frequencies to enable capture of depth sensing information that may vary based on frequency, according to an embodiment. Fringe projector 504 and fringe projector 506 may be operated sequentially to illuminate the eye with two fringe patterns at two frequencies at different times, according to an embodiment.

Fringe projector 504 includes a light source 508, a waveguide structure 510, and outcoupling elements 512A and 512B, according to an embodiment. Light source 508 may be a laser configured to emit light at a first wavelength (e.g., 850 nm) to cause the outcoupling elements 512A and 512B to generate a first fringe pattern at the first wavelength.

Fringe projector 506 includes a light source 514, a waveguide structure 516, and outcoupling elements 518A and 518B, according to an embodiment. Light source 514 may be a laser configured to emit light at a second wavelength (e.g., 940 nm) to cause the outcoupling elements 518A and 518B to generate a second fringe pattern at the second wavelength. The spacing of the outcoupling elements 518A and 518B may be different than the spacing of outcoupling elements 512A and 512B. For example, outcoupling elements 512A and 512B may be spaced 25 μm apart and outcoupling elements 518A and 518B may be spaced 40 μm apart. In one implementation, the spacing between the different outcoupling elements is the same.

Fringe projectors 504 and 506 may have a variety of configurations. For example, the fringe projectors are illustrated as being perpendicular to each other. However, the general angle between the fringe projectors may be greater than or less than 90°. Additionally, more than two fringe projectors may be used to generate fringe patterns with more than two wavelengths. For example, optical element 502 may be coupled to four different fringe projectors and each of the four fringe projectors may be configured to generate a fringe projector at a different wavelength (e.g., 850 nm, 890 nm, 940 nm, 990 nm). Additionally, the features of one or more of any other fringe projector disclosed herein may be combined with fringe projector 504 or 506 to generate fringe patterns at different wavelengths, chirped fringe patterns, and/or fringe patterns generated by selectively using an optical delay in one channel.

Controller 130 may be coupled to light source 508, light source 514, and sensor 524. Controller 130 may be communicatively coupled to light source 508 through a communication channel 520 to send control signals to turn light source 508 on and off and to set or adjust the operating wavelength or frequency of light source 508. Controller 130 may be communicatively coupled to light source 514 through a communication channel 522 to send control signals to turn light source 514 on and off and to set or adjust the operating wavelength or frequency of light source 514. Sensor 524 may include a color filter array (CFA) that passes a first wavelength of light for some of the pixels (e.g., half of the pixels), and that passes a second wavelength of light for others of the pixels. The CFA may have a checkerboard pattern of filters for the first and second wavelengths. Controller 130 may be coupled to sensor 524 through a communication channel 526 to receive image data 133. Controller 130 is configured to use image data 133 to determine a depth map (e.g., a 3D depth map) of the eye of a user, according to an embodiment. Controller 130 may operate light sources 508 and 514 at the same time (concurrently) or sequentially (one after the other, repeatedly). In one implementation, two sensors are used, where a first sensor images light of a first wavelength (e.g., 850 nm) and a second sensor images light of a second wavelength (e.g., 940 nm).

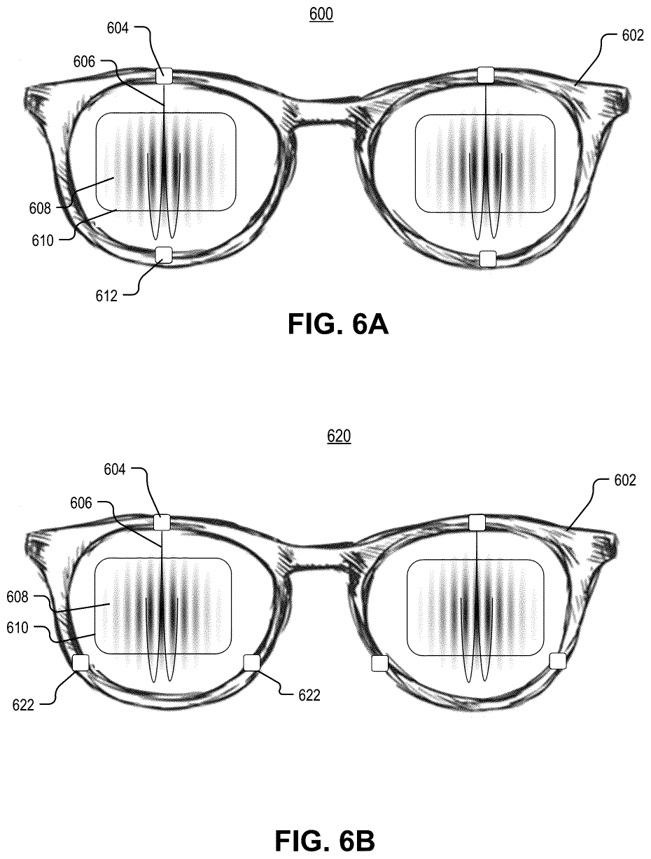

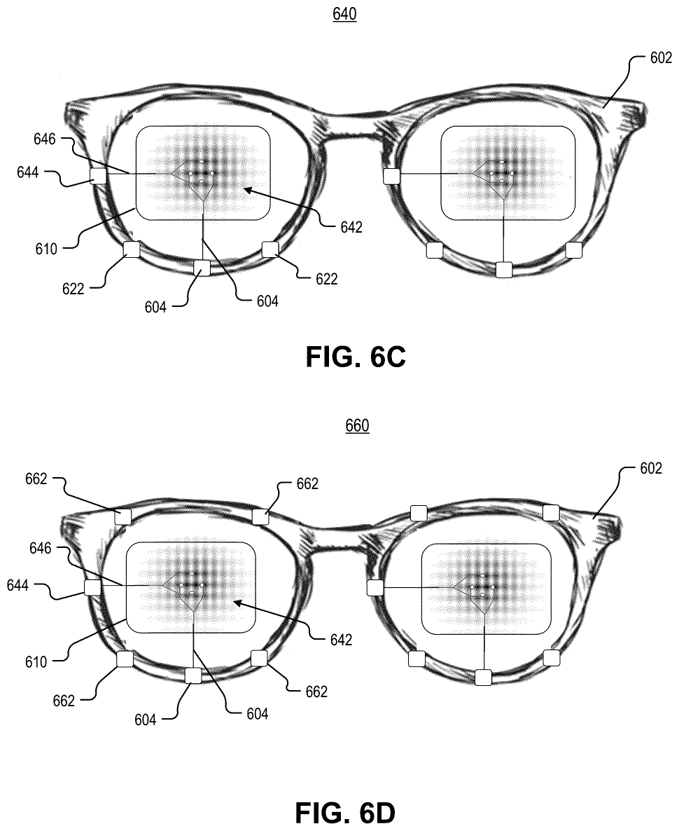

FIGS. 6A, 6B, 6C, and 6D illustrate various light source and sensor configurations for a head mounted device, in accordance with aspects of the disclosure. The various configurations may be used to support eye tracking operations.

FIG. 6A illustrates an example of a head mounted device 600 configured to use a depth sensing system to support eye tracking operations, in accordance with aspects of the disclosure. Head mounted device 600 may include a frame 602. The depth sensing system may include a single light source 604 positioned in frame 602. Light source 604 may be optically coupled to a waveguide structure 606 that is configured to generate a fringe pattern 608 in an eye region 610. The depth sensing system may include a single sensor 612 that is positioned in or on frame 602 and is configured to image eye region 610 to capture reflections of fringe pattern 608. A fringe projector or fringe projection system may include light sources, waveguide structures, and outcoupling elements. The depth sensing system may include the fringe projector, one or more sensors, and one or more controllers. The depth sensing system may be implemented in optical elements on both sides of head mounted device 600.

FIG. 6B illustrates an example of a head mounted device 620 configured to use a depth sensing system to support eye tracking operations, in accordance with aspects of the disclosure. The depth sensing system may include two (or more) sensors 622 that are positioned in or on frame 602 and are configured to image eye region 610 to capture reflections of fringe pattern 608. The depth sensing system may be implemented in optical elements on both sides of head mounted device 620.

FIG. 6C illustrates an example of a head mounted device 640 configured to use a depth sensing system to support eye tracking operations, in accordance with aspects of the disclosure. In addition to sensors 622, the depth sensing system may include two fringe projectors configured to generate misaligned fringe patterns 642. Fringe patterns 642 may have interference patterns that are misaligned by 90° or some other angle. A first fringe projector may include light source 644, waveguide 646, and first outcoupling elements. A second fringe projector may include light source 648, waveguide 650, and second outcoupling elements. The depth sensing system may include the first fringe projector, the second fringe projector, and sensors 622. Sensors 622 may be positioned at a number of locations on frame 602 to image fringe patterns 642. The depth sensing system may be implemented in optical elements on both sides of head mounted device 640.

FIG. 6D illustrates an example of a head mounted device 660 configured to use a depth sensing system to support eye tracking operations, in accordance with aspects of the disclosure. The depth sensing system may include four (or more) sensors 662 that are positioned in or on frame 602 and are configured to image eye region 610 to capture reflections of fringe pattern 642. The depth sensing system may be implemented in optical elements on both sides of head mounted device 660.

In an implementation of the disclosure, a fringe projector disposed on a transparent substrate utilizes photonic integrated circuits for AR/VR applications such as eye-tracking and/or face tracking with depth sensing. Multiple light sources may be used. Multiple light sources may be integrated on a same substrate with photonic waveguides. In some implementations, a metallic mirror is used as the outcoupling elements and the outcoupling elements are fabricated on the same substrate.

In an implementation of the disclosure, a device with an optical path induces delay for phase shifting to support depth sensing.

In an implementation of the disclosure, a device with a light source can be tuned with its wavelength to manipulate phase shifting.

Implementations of the disclosure include wavelength and time multiplexed system configuration for accurate and fast 3D sensing. The fringe projectors may be realized with photonic integrated circuits and disposed in a FOV of a user (“in-field”). Because of the small size of the fringe projector and the close proximity to the user's eye, the fringe projector may not be noticeable to the user even though it is disposed within the user's FOV.

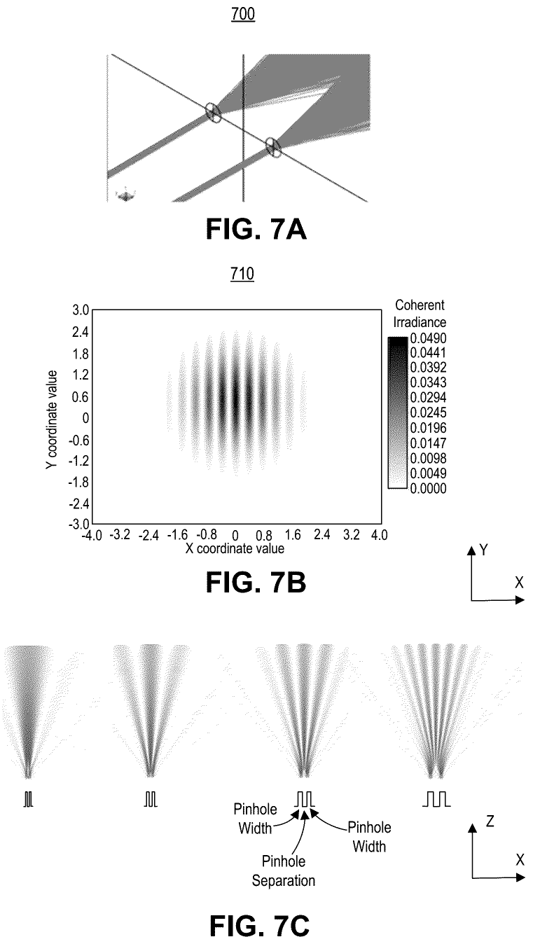

FIGS. 7A, 7B, and 7C illustrate various aspects of interferometric fringe generation with pinhole separation and fringe spatial frequencies. FIG. 7A illustrates pinhole fringe generator 700 that receives Gaussian light beams through pinholes separated by 40 μm to cause output light beam interference. FIG. 7B illustrates a fringe pattern 710 that may result from fringe generator 700. FIG. 7C illustrates how light beam interference may be manipulated by aperture size and spacing to customize characteristics (e.g., interference line spacing) of interference patterns.

In an implementation of the disclosure, a fringe projector disposed on a transparent substrate utilizes photonic integrated circuits for AR/VR applications such as eye-tracking and/or face tracking with depth sensing. Multiple light sources may be used. Multiple light sources may be integrated on a same substrate with photonic waveguides. In some implementations, a metallic mirror is used as the output couplers and the output couplers are fabricated on the same substrate.

In an implementation of the disclosure, a device with an optical path induces delay for phase shifting needed for depth tracking.

In an implementation of the disclosure, a device with a light source can be tuned with its wavelength to effect phase shifting.

Implementations of the disclosure include wavelength and time multiplexed system configuration for accurate and fast 3D sensing. The fringe projectors are realized with photonic integrated circuits and disposed in a FOV of a user (“in-field”). Because of the small size of the fringe projector and the close proximity to the user's eye, the fringe projector may not be noticeable to the user even though it is disposed within the user's FOV.

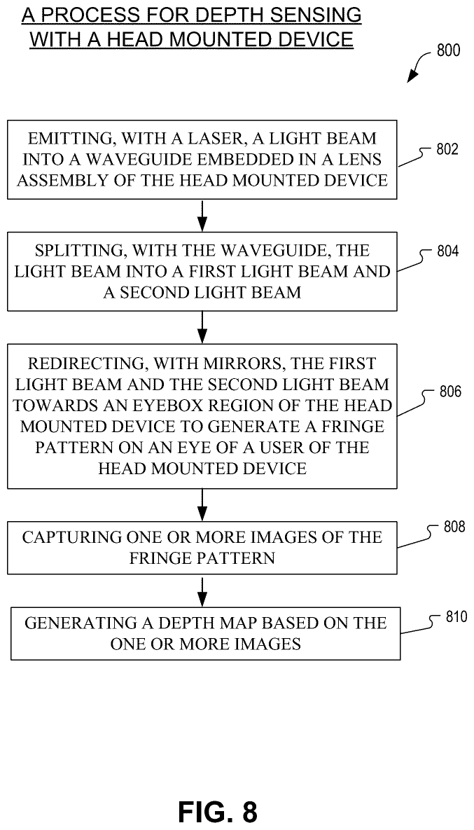

FIG. 8 illustrates an example flow diagram of a process 800 for depth sensing with a head mounted device, in accordance with aspects of the disclosure. Process 800 may be at least partially incorporated into one or more head mounted devices, according to an embodiment. The order in which some or all of the process blocks appear in process 800 should not be deemed limiting. Rather, one of ordinary skill in the art having the benefit of the present disclosure will understand that some of the process blocks may be executed in a variety of orders not illustrated, or even in parallel.

At process block 802, process 800 emits, with a laser, a light beam into a waveguide embedded in a lens assembly of a head mounted device, according to an embodiment. Process block 802 proceeds to process block 804, according to an embodiment.

At process block 804, process 800 splits, with the waveguide, the light beam into a first light beam and a second light beam, according to an embodiment. Process block 804 proceeds to process block 806, according to an embodiment.

At process block 806, process 800 redirecting, with mirrors, the first light beam and the second light beam towards an eyebox region of the head mounted device to generate a fringe pattern on an eye of a user of the head mounted device, according to an embodiment. Process block 806 proceeds to process block 808, according to an embodiment.

At process block 808, process 800 capturing one or more images of the fringe pattern, according to an embodiment. Process block 806 proceeds to process block 808, according to an embodiment.

At process block 810, process 800 generates a depth map based on the one or more images, according to an embodiment.

Embodiments of the invention may include or be implemented in conjunction with an artificial reality system. Artificial reality is a form of reality that has been adjusted in some manner before presentation to a user, which may include, e.g., a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, and any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, e.g., create content in an artificial reality and/or are otherwise used in (e.g., perform activities in) an artificial reality. The artificial reality system that provides the artificial reality content may be implemented on various platforms, including a head-mounted display (HMD) connected to a host computer system, a standalone HMD, a mobile device or computing system, or any other hardware platform capable of providing artificial reality content to one or more viewers.

The term “processing logic” (e.g. controller 130) in this disclosure may include one or more processors, microprocessors, multi-core processors, Application-specific integrated circuits (ASIC), and/or Field Programmable Gate Arrays (FPGAs) to execute operations disclosed herein. In some embodiments, memories (not illustrated) are integrated into the processing logic to store instructions to execute operations and/or store data. Processing logic may also include analog or digital circuitry to perform the operations in accordance with embodiments of the disclosure.

A “memory” or “memories” described in this disclosure may include one or more volatile or non-volatile memory architectures. The “memory” or “memories” may be removable and non-removable media implemented in any method or technology for storage of information such as computer-readable instructions, data structures, program modules, or other data. Example memory technologies may include RAM, ROM, EEPROM, flash memory, CD-ROM, digital versatile disks (DVD), high-definition multimedia/data storage disks, or other optical storage, magnetic cassettes, magnetic tape, magnetic disk storage or other magnetic storage devices, or any other non-transmission medium that can be used to store information for access by a computing device.

A network may include any network or network system such as, but not limited to, the following: a peer-to-peer network; a Local Area Network (LAN); a Wide Area Network (WAN); a public network, such as the Internet; a private network; a cellular network; a wireless network; a wired network; a wireless and wired combination network; and a satellite network.

Communication channels (e.g., 131 and 132) may include or be routed through one or more wired or wireless communication utilizing IEEE 802.11 protocols, short-range wireless protocols, SPI (Serial Peripheral Interface), I2C (Inter-Integrated Circuit), USB (Universal Serial Port), CAN (Controller Area Network), cellular data protocols (e.g. 3G, 4G, LTE, 5G), optical communication networks, Internet Service Providers (ISPs), a peer-to-peer network, a Local Area Network (LAN), a Wide Area Network (WAN), a public network (e.g. “the Internet”), a private network, a satellite network, or otherwise.

A computing device may include a desktop computer, a laptop computer, a tablet, a phablet, a smartphone, a feature phone, a server computer, or otherwise. A server computer may be located remotely in a data center or be stored locally.

The processes explained above are described in terms of computer software and hardware. The techniques described may constitute machine-executable instructions embodied within a tangible or non-transitory machine (e.g., computer) readable storage medium, that when executed by a machine will cause the machine to perform the operations described. Additionally, the processes may be embodied within hardware, such as an application specific integrated circuit (“ASIC”) or otherwise.

A tangible non-transitory machine-readable storage medium includes any mechanism that provides (i.e., stores) information in a form accessible by a machine (e.g., a computer, network device, personal digital assistant, manufacturing tool, any device with a set of one or more processors, etc.). For example, a machine-readable storage medium includes recordable/non-recordable media (e.g., read only memory (ROM), random access memory (RAM), magnetic disk storage media, optical storage media, flash memory devices, etc.).

The above description of illustrated embodiments of the invention, including what is described in the Abstract, is not intended to be exhaustive or to limit the invention to the precise forms disclosed. While specific embodiments of, and examples for, the invention are described herein for illustrative purposes, various modifications are possible within the scope of the invention, as those skilled in the relevant art will recognize.

These modifications can be made to the invention in light of the above detailed description. The terms used in the following claims should not be construed to limit the invention to the specific embodiments disclosed in the specification. Rather, the scope of the invention is to be determined entirely by the following claims, which are to be construed in accordance with established doctrines of claim interpretation.

What is claimed is:

1. An optical system comprising:
a transparent layer;
at least one laser optically coupled to the transparent layer and configured to emit light into the transparent layer;
a first output coupler positioned in a first location of the transparent layer and configured to out-couple a first portion of the light from the first location of the transparent layer; and
a second output coupler positioned in a second location of the transparent layer and configured to out-couple a second portion of the light from the second location of the transparent layer,
wherein a combination of the first portion of the light and the second portion of the light out-coupled from the first output coupler and the second output coupler is configured to generate a fringe pattern.

2. The optical system of claim 1 further comprising:
a waveguide positioned in the transparent layer, wherein the waveguide is optically coupled between the at least one laser, the first output coupler, and the second output coupler.

3. The optical system of claim 2, wherein the waveguide includes a first segment and a second segment, wherein the first segment is coupled between the at least one laser and the first output coupler to carry the first portion of the light, wherein the second segment is coupled between the at least one laser and the second output coupler to carry the second portion of the light.

4. The optical system of claim 3, wherein a first length of the first segment is longer than a second length of the second segment, wherein a difference between the first length and the second length is configured to optically delay and shift a phase of the first portion of the light in the first segment.

5. The optical system of claim 2, wherein the waveguide includes one or more of SiN, Si, and lithium niobate, wherein the transparent layer includes SiO2.

6. The optical system of claim 2, wherein the waveguide includes a first refractive index and the transparent layer includes a second refractive index, wherein the first refractive index is higher than the second refractive index.

7. The optical system of claim 2, wherein the first output coupler or the second output coupler is positioned at a 45 degree angle with respect to the transparent layer or with respect to the waveguide.

8. The optical system of claim 2, wherein the fringe pattern is a first fringe pattern, wherein the waveguide is a first waveguide, wherein the at least one laser includes a first laser and a second laser, wherein the light is first light, wherein the first laser is coupled to emit the first light in the first waveguide, wherein the second laser is configured to emit second light, wherein the optical system further includes:
a second waveguide coupled to receive the second light from the second laser;
a third output coupler positioned in a third location of the transparent layer and configured to out-couple a first portion of the second light from the third location of the transparent layer; and
a fourth output coupler positioned in a fourth location of the transparent layer and configured to out-couple a second portion of the second light from the fourth location of the transparent layer concurrently with the first portion of the second light out-coupled from the third location of the transparent layer,
wherein a combination of the first and second portions of the second light out-coupled from the third and fourth output couplers is configured to generate a second fringe pattern.

9. The optical system of claim 8, wherein the first laser emits the first light with a first wavelength, wherein the second laser emits the second light with a second wavelength, wherein the second wavelength is greater than the first wavelength.

10. The optical system of claim 8, wherein the first laser and the second laser are configured to be operated sequentially.

11. The optical system of claim 1, wherein the first location and the second location are in a field of view of an eye of a user the optical system.

12. The optical system of claim 1, wherein the at least one laser includes an edge emission laser or a vertical cavity surface emitting laser (VCSEL).

13. A head mounted display (HMD) comprising:
a frame;
a transparent layer carried by the frame;
a fringe projector coupled to the transparent layer and configured to generate a fringe pattern in an eyebox region of the HMD, wherein the fringe projector includes:
a laser optically coupled to the transparent layer and configured to emit light into the transparent layer;
a first output coupler positioned in a first location of the transparent layer and configured to out-couple the light from the first location of the transparent layer; and
a second output coupler positioned in a second location of the transparent layer and configured to out-couple the light from the second location of the transparent layer,
wherein the light out-coupled from the first and second locations is configured to generate the fringe pattern; and
at least one image sensor coupled to the frame and oriented towards the eyebox region of the HMD, wherein the at least one image sensor is configured to generate image data representative of an image of the fringe pattern.

14. The HMD of claim 13 further comprising:
a controller coupled to the laser and coupled to the at least one image sensor, wherein the controller is configured to operate the laser and is configured to receive the image data from the image sensor, wherein the controller is configured to generate a 3D depth map of at least part of the eyebox region.

15. The HMD of claim 13 further comprising:
a waveguide positioned in the transparent layer, wherein the waveguide is optically coupled between the laser, the first output coupler, and the second output coupler.

16. The HMD of claim 15, wherein the waveguide includes a first segment and a second segment, wherein the first segment is coupled between the laser and the first output coupler, wherein the second segment is coupled between the laser and the second output coupler.

17. The HMD of claim 16, wherein a first length of the first segment is longer than a second length of the second segment, wherein a difference between the first length and the second length is configured to optically delay the light in the first segment to shift a phase of the light in the first segment.

18. A method of depth sensing with a head mounted device comprising:
emitting, with a laser, a light beam into a waveguide embedded in a lens assembly of a head mounted device;
splitting, with the waveguide, the light beam into a first light beam and a second light beam;
redirecting, with output couplers, the first light beam and the second light beam towards an eyebox region of the head mounted device to generate a fringe pattern on an eye of a user of the head mounted device;
capturing one or more images of the fringe pattern; and
generating a depth map based on the one or more images.

19. The method of claim 18 further comprising:
modifying a wavelength of the laser to change a phase of the first and second light beams to alter characteristics of the fringe pattern.

20. The method of claim 18, wherein the laser is a first laser, wherein the waveguide is a first waveguide, wherein the fringe pattern is a first fringe pattern, wherein the method further comprises:
emitting, with a second laser, a third light beam into a second waveguide to generate a second fringe pattern that is approximately co-located with the first fringe pattern; and
generating the depth map based on the first and second fringe patterns.
